(19) United States
(12) Patent Application Publication
(10) Pub. No.: US 2017/0068762 A1
(43) Pub. Date: Mar. 9, 2017

(54) SIMULATION DEVICE, SIMULATION PROGRAM, AND SIMULATION METHOD

(71) Applicant: FUJITSU LIMITED, Kawasaki-shi (JP)

(72) Inventor: Koichi Shimizu, Inagi (JP)

(73) Assignee: FUJITSU LIMITED, Kawasaki-shi (JP)

(21) Appl. No.: 15/253,912

(22) Filed: Sep. 1, 2016

(30) Foreign Application Priority Data
Sep. 4, 2015 (JP) 2015-174874

(51) Int. Cl. G06F 17/50; G01N 27/72; G06F 17/16; G01R 33/14

(52) U.S. Cl. CPC G06F 17/5018; G01R 33/14; G01N 27/72; G06F 17/16

(57) ABSTRACT

A simulation method for causing a computer to execute a process, the process includes: calculating, based on information associated with edge elements with which an acquired calculation target is modeled and information of Gaussian numerical integration points in a cell element surrounded by the plurality of edge elements, using a finite element method, a magnetic flux density vector for each of the Gaussian numerical integration points, and calculating a magnetization vector for each of the Gaussian numerical integration points, based on the magnetic flux density vector and a plurality of microscopic magnetization vectors associated with the Gaussian numerical integration points.

### CROSS-REFERENCE TO RELATED APPLICATION

This application is based upon and claims the benefit of priority of the prior Japanese Patent Application No. 2015-174874, filed on Sep. 4, 2015, the entire contents of which are incorporated herein by reference.

### FIELD

The embodiments discussed herein are related to a simulation device, a simulation program, and a simulation method.

### BACKGROUND

A method in which magnetic field analysis is performed using a finite element method has been described in Takahashi, Norio, “Optimization using magnetic field system finite element method”, Morikita Publishing Co., Ltd., May 2001, and Honma, Toshihisa, Igarashi, Hajime, and Kawaguchi, Hideo, “Calculation electrical and electronics engineering series 14, Numerical electromagnetic dynamics—Foundation and application—”, Morikita Publishing Co., Ltd., July 2002.

An analysis method in which magnetic field analysis using a finite element method and calculation of a magnetization vector based on the Landau-Lifshitz-Gilbert (LLG) equation are alternately performed to analyze characteristics of a magnetic body has been described in Japanese Laid-open Patent Publication No. 2013-131072. The LLG equation used herein is an equation which may be used to represent an effect of a magnetic field on a ferromagnetic substance.

An analysis method in which, when iterative calculation based on the LLG equation is used, if a change amount of a calculated magnetization vector exceeds a predetermined value, the magnetization vector is recorded has been described in Japanese Laid-open Patent Publication No. 2015-103189.

The relationship between the intensity of a magnetic field that is externally applied to a magnetic material and the intensity of magnetization that is generated in the magnetic material depends on the intensity of an external magnetic field that has been previously applied to the magnetic material. This characteristic is called magnetic hysteresis. In each of the analysis methods of Takahashi, Norio, “Optimization using magnetic field system finite element method”, Morikita Publishing Co., Ltd., May 2001, and Honma, Toshihisa, Igarashi, Hajime, and Kawaguchi, Hideo, “Calculation electrical and electronics engineering series 14, Numerical electromagnetic dynamics—Foundation and application—”, Morikita Publishing Co., Ltd., July 2002, when magnetic field analysis is performed, it is not possible to take magnetic hysteresis into consideration with high accuracy.

In each of the analysis methods of Japanese Laid-open Patent Publication No. 2013-131072 and Japanese Laid-open Patent Publication No. 2015-103189, analysis accuracy depends largely on the number of divisions in modeling an analysis target. Therefore, in order to perform a highly accurate analysis, a preliminary analysis is performed using a plurality of models having different numbers of divisions in a stage in which the number of divisions for each model is determined. This increases the total calculation amount for all analysis process steps.

In one aspect, it is an object of the present disclosure to provide a simulation method in which a highly accurate simulation is performed with a small calculation amount, or the like.

### SUMMARY

According to an aspect of the invention, in a simulation method for causing a computer to execute a process, the process includes: calculating, based on information associated with edge elements with which an acquired calculation target is modeled and information of Gaussian numerical integration points in a cell element surrounded by the plurality of edge elements, using a finite element method, a magnetic flux density vector for each of the Gaussian numerical integration points, and calculating a magnetization vector for each of the Gaussian numerical integration points, based on the magnetic flux density vector and a plurality of microscopic magnetization vectors associated with the Gaussian numerical integration points.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram illustrating a configuration of a simulation device;

FIG. 2 is a view illustrating an example of an analysis target;

FIG. 3 is a view illustrating an example in which an analysis target is divided;

FIG. 4 is a view illustrating edge elements;

FIG. 5 is a view illustrating Gaussian numerical integration points and a divided element;

FIG. 6 is a view illustrating microscopic magnetization vectors;

FIG. 7A and FIG. 7B are views illustrating a vector potential, a magnetic flux density vector, and a magnetization vector;

FIG. 8 is a table illustrating the layout of a record of a magnetization vector DB;

FIG. 9 is a table illustrating the layout of a record of a magnetic flux density vector DB;

FIG. 10 is a table illustrating the layout of a record of a microscopic magnetization vector DB;

FIG. 11 is a table illustrating the layout of a record of a vector potential DB;

FIG. 12 is a chart illustrating an outline of a simulation method;

FIG. 13 is a flow chart illustrating a flow of processing of a program;

FIG. 14 is a flow chart illustrating a flow of processing of a subroutine of magnetic field analysis;

FIG. 15 is a flow chart illustrating a flow of processing of a subroutine of hysteresis model calculation;

FIG. 16A to FIG. 16F are views illustrating examples for which the number of divisions of an analysis target is changed;

FIG. 17 is a graph illustrating a convergent state of an analysis result;

FIG. 18 is a flow chart illustrating a flow of processing of a program according to a second embodiment;

FIG. 19 is a flow chart illustrating a flow of processing of a subroutine of hysteresis model calculation according to the second embodiment;

FIG. 20 is a functional block diagram illustrating an operation of a simulation device according to a third embodiment; and

FIG. 21 is a diagram illustrating a configuration of a simulation device according to a fourth embodiment.

### DESCRIPTION OF EMBODIMENTS

### First Embodiment

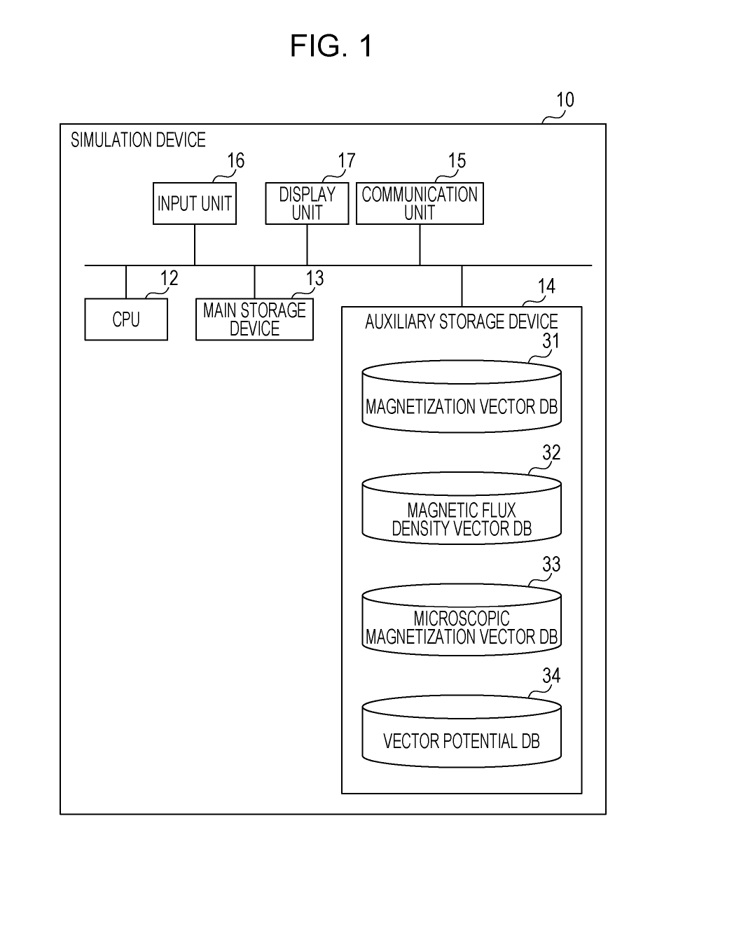

FIG. 1 is a diagram illustrating a configuration of a simulation device 10. The simulation device 10 includes a central processing unit (CPU) 12, memory, such as a main storage device 13, an auxiliary storage device 14, or the like, a communication unit 15, an input unit 16, a display unit 17, and a bus. The simulation device 10 according to this embodiment uses an information device, such as a general-purpose personal computer, a tablet, or the like.

The CPU 12 is an arithmetic and control device that executes a program according to this embodiment and may be a processor, such as a microprocessor (MPU) or the like. As the CPU 12, one or more CPUs, multi-core CPUs, or the like are used. The CPU 12 is coupled to each of a plurality of hardware components that form the simulation device 10 via the bus.

The main storage device 13 is a storage device, such as static random access memory (SRAM), dynamic random access memory (DRAM), flash memory, or the like. Information used while processing is performed by the CPU 12 and a program that is executed by the CPU 12 are temporarily stored in the main storage device 13.

The auxiliary storage device 14 is a storage device, such as SRAM, flash memory, a hard disk, a magnetic tape, or the like. A program that the CPU 12 is caused to execute, and various types of information, such as a magnetization vector database (DB) 31, a magnetic flux density vector DB 32, a microscopic magnetization vector DB 33, a vector potential DB 34, or the like, which are used for executing the program, are stored in the auxiliary storage device 14.

The communication unit 15 is an interface that performs communication with a network, such as the Internet, an intranet, or the like, which is not illustrated in FIG. 1.

The input unit 16 is a device, such as a mouse, a keyboard, a touch panel, a pen tablet, a microphone, or the like, and is used when the simulation device 10 receives an operation input by a user. The display unit 17 is a device, such as a display, a printer, a plotter, and or the like, and displays a simulation result or the like.

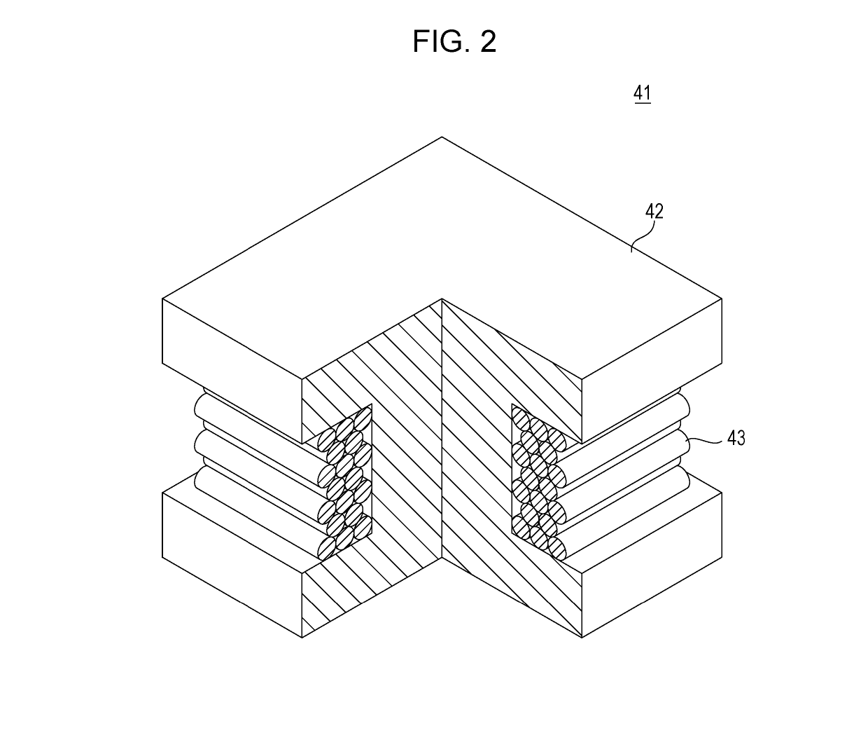

FIG. 2 is a view illustrating an example of an analysis target. FIG. 2 is a view of an inductor 41 with a cutaway to illustrate an inner structure. The inductor 41 is a passive component that is used for various electric circuits. In this embodiment, three-dimensional magnetic field analysis of the inductor 41 is performed.

The inductor 41 includes a core 42 and a lead 43. The shape of the core 42 is obtained by uniting two square plates with a square pillar interposed therebetween. As a material of the core 42, for example, ferrite is used. The lead 43 is a metal wire wound around the pillar of the core 42. As the lead 43, a copper wire, an aluminum wire, or the like having an insulating coating is used.

Note that a target that is analyzed by the simulation device 10 is not limited to the inductor 41 illustrated in FIG. 2. The simulation device 10 may perform analysis of various devices and components, such as a motor, a transformer, a magnetic head, a memory device, a contactless feeding device, or the like, which use magnetism.

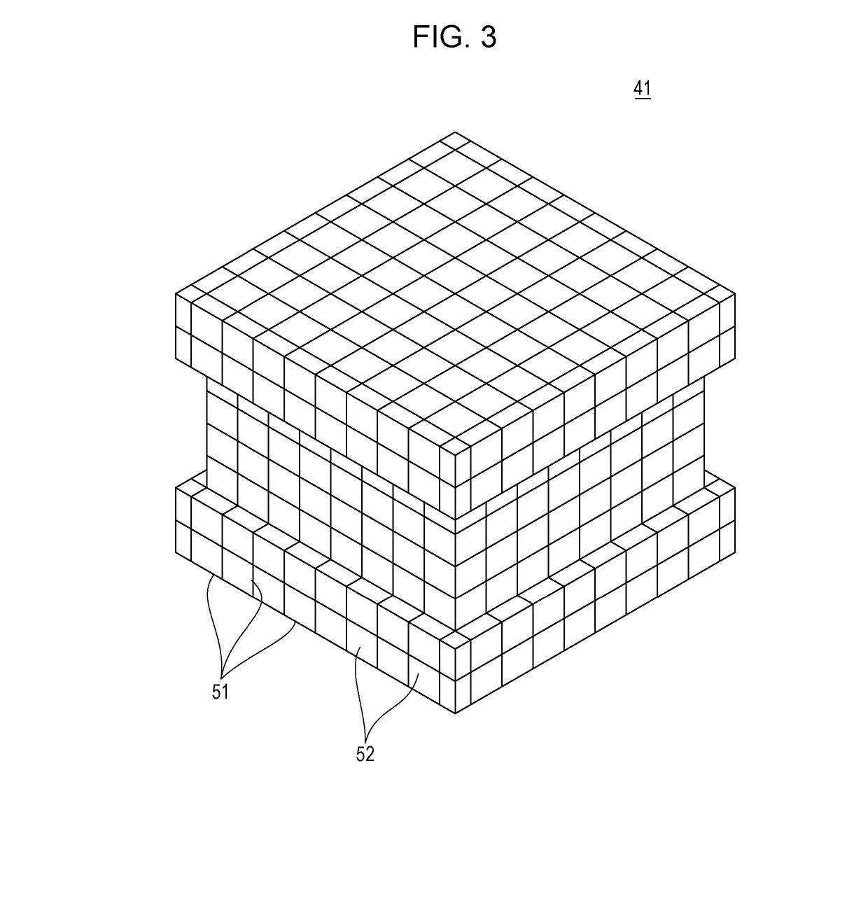

FIG. 3 is a view illustrating an example in which an analysis target is divided. In this embodiment, the inductor 41 is divided by three-dimensionally reticulated edge elements 51 into hexahedral cell elements 52, each of which is surrounded by twelve edge elements 51. Note that, similar to the inductor 41, the circumambient air of the inductor 41 is divided. Division of air is not illustrated.

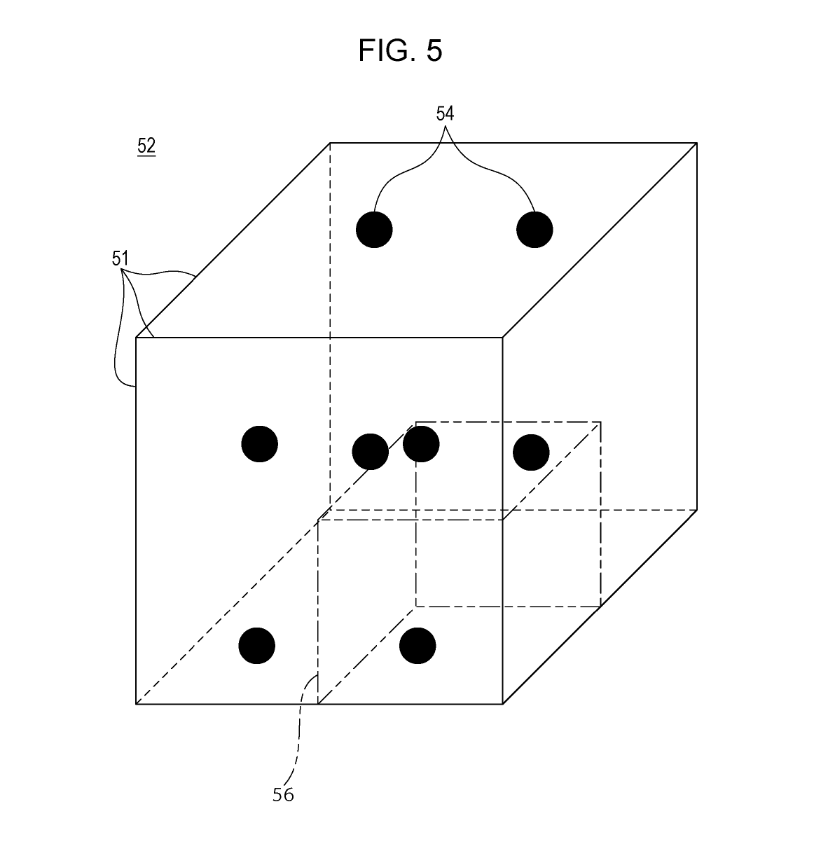

Division is performed using a mesh division tool that has been conventionally used for analysis of a magnetic body using a finite element method. The mesh division tool receives input of analysis conditions, such as dimensions, a physical property value, constraint conditions, and initial conditions, the number of divisions, or the like of an analysis target and outputs a connection relation between the edge elements 51 and constraint conditions thereof, a positional relation between the edge elements 51 and Gaussian numerical integration points 54 (see FIG. 5), which will be described later, and an arrangement having, as an element, a value associated with each Gaussian numerical integration point 54 and the corresponding edge elements 51. The arrangement that has been output is stored in the auxiliary storage device 14. In the following description, an operation of inputting analysis conditions to the mesh division tool and storing information used in subsequent analysis is called modeling.

The mesh division tool may be used to divide an analysis target, for example, by using pentahedral elements or tetrahedral elements. Also, the mesh division tool may be used to divide an analysis target, for example, by using hexahedral elements, pentahedral elements, and tetrahedral elements in combination.

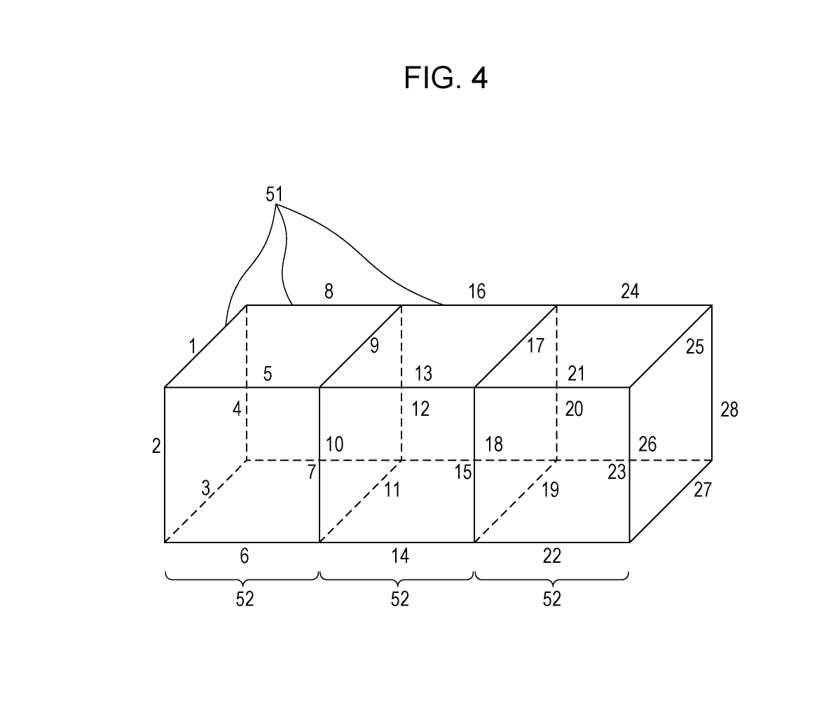

FIG. 4 is a view illustrating the edge elements 51. FIG. 4 is a view illustrating three successive cell elements 52 of an analysis target. Adjacent cell elements 52 share corresponding edge elements 51. Serial numbers are given to the edge elements 51.

FIG. 5 is a view illustrating Gaussian numerical integration points 54 and a divided element 56. FIG. 5 is a view illustrating a single cell element 52 of an analysis target. The cell element 52 includes eight Gaussian numerical integration points 54 therein. Serial numbers (not illustrated) are given to the Gaussian numerical integration points 54. The Gaussian numerical integration points 54 are virtual points that are used to efficiently perform calculation of a finite element method.

The cell element 52 is divided into eight divided elements 56, each of which includes an associated one of the Gaussian numerical integration points 54. A single divided element 56 is indicated by the alternating long and two-short-dashes line.

Note that the number of the Gaussian numerical integration points 54 differs depending on the shape of the cell elements 52 used. For example, a quadrangular element that is used in two-dimensional analysis includes four Gaussian numerical integration points 54. Accordingly, the quadrangular element is divided into four divided elements 56.

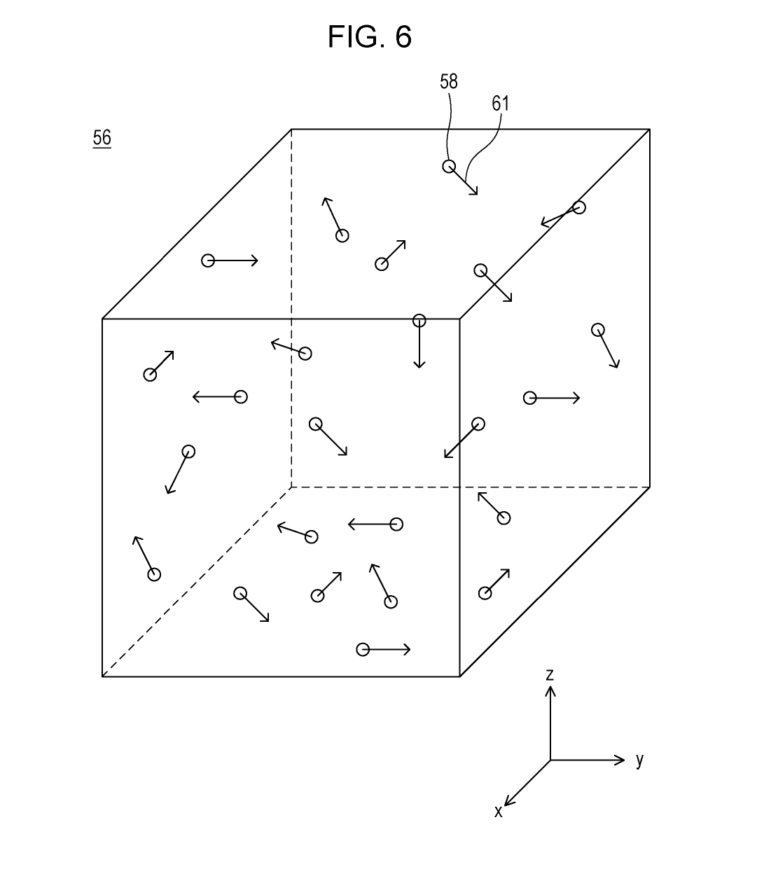

FIG. 6 is a view illustrating microscopic magnetization vectors m61. FIG. 6 is a view illustrating a single divided element 56 of the cell element 52. About 500,000 elements 58 are arranged in the single divided element 56. In this embodiment, the elements 58 are arranged at random.

Each of the elements 58 has a microscopic magnetization vector m61. The microscopic magnetization vector m61 is a one-dimensional vector that has components in three directions x, y, and z. For each divided element 56, serial numbers starting with 1 (not illustrated) are given to the microscopic magnetization vectors m61.

By calculating an average vector of the microscopic magnetization vectors m61 in a single divided element 56, a magnetization vector M associated with the Gaussian numerical integration points 54 in the divided element 56 may be calculated. The magnetization vector M used herein is a vector that indicates the intensity of magnetization that is generated in the divided element 56 when a magnetic field is externally applied and that indicates the orientation of the magnetization. The average vector is a vector calculated by averaging the components of each magnetization vector M in the three directions x, y, and z for each direction. The magnetization vector M is a one-dimensional vector having components in the three directions x, y, and z.

Also, by calculating the average vector of all of the microscopic magnetization vectors m61 included in the cell element 52 including the Gaussian numerical integration points 54, the magnetization vector <M> associated with the cell element 52 may be calculated.

Note that the elements 58 may be elements obtained by dividing the divided element 56 into hexahedrons, pentahedrons, tetrahedrons, or the like. Thus, highly accurate analysis considering a static magnetic field and an exchange coupling field between the elements 58 may be performed.

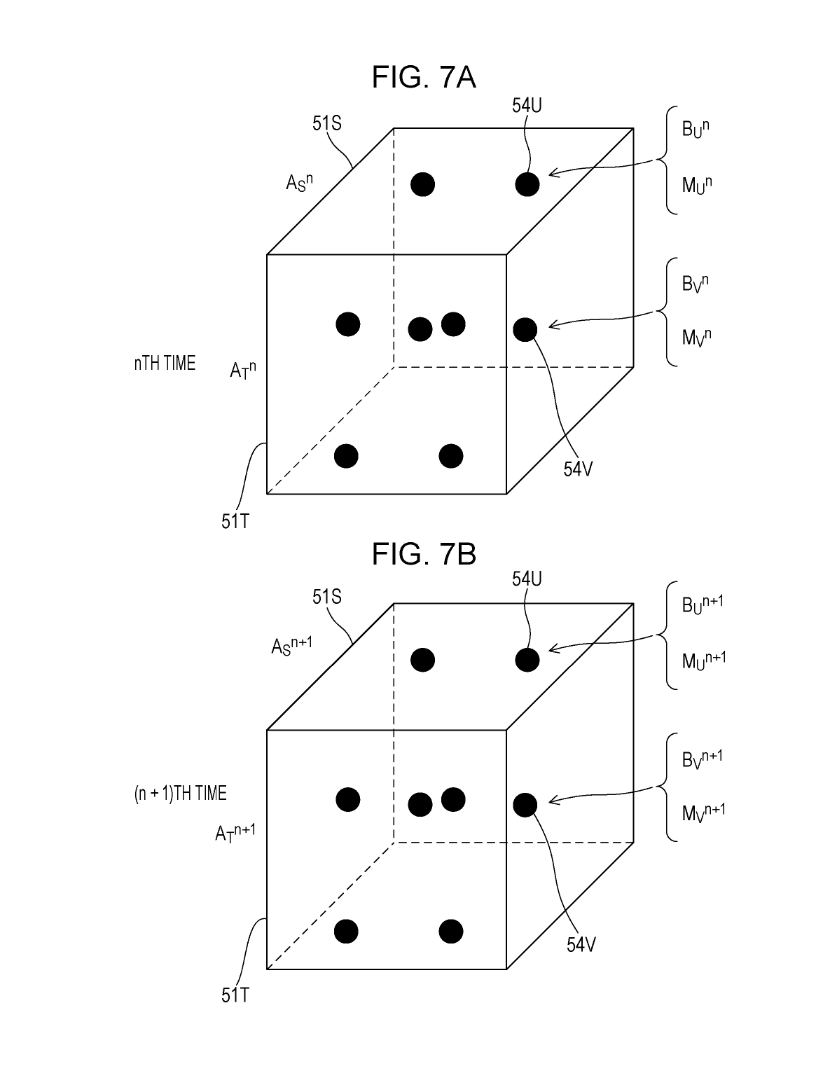

FIG. 7A and FIG. 7B are views illustrating a vector potential A, a magnetic flux density vector B, and a magnetization vector M. Each of FIG. 7A and FIG. 7B is a view illustrating a single cell element 52 of an analysis target. FIG. 7A illustrates an initial state of nth iterative calculation, and FIG. 7B illustrates an initial state of (n+1)th iterative calculation.

As described above, the single cell element 52 is surrounded by twelve edge elements 51. Also, in the single cell element 52, there are eight Gaussian numerical integration points 54. The vector potential A is associated with the edge elements 51. The magnetic flux density vector B and the magnetization vector M are associated with the Gaussian numerical integration points 54.

In this case, the vector potential A used herein is an unknown that is used in performing magnetic field analysis using a finite element method. The magnetic flux vector B is a vector that indicates a magnetic flux surface density. The magnetic flux density vector B is a one-dimensional vector having components in the three directions x, y, and x.

The following description will be given using an example including an Sth edge element 51S, a Tth edge element 51T, a Uth Gaussian numerical integration point 54U, and a Vth Gaussian numerical integration point 54V. In the following description, a subscript denotes the number of the edge element 51 or the Gaussian numerical integration point 54, and a superscript denotes the number of times calculation is performed. For example, a vector potential A_{T}ⁿ denotes the vector potential A associated with the Tth edge element 51T in the initial state of the nth repeated calculation. A magnetic flux density vector Bᵤⁿ denotes the magnetic flux density vector B associated with the Uth Gaussian numerical integration point 54 in the initial state of the nth repeated calculation. A magnetization vector Mᵥⁿ denotes the magnetization vector M associated with the Vth Gaussian numerical integration point 54 in the initial state of the nth repeated calculation.

As illustrated in FIG. 7B, when single repeated calculation is performed, the vector potential A_{T}ⁿ changes to a vector potential A_{T}ⁿ⁺¹, the magnetic flux density vector Bᵤⁿ changes to a magnetic flux density vector Bᵤⁿ⁺¹, and the magnetization vector Mᵥⁿ changes to a magnetization vector Mᵥⁿ⁺¹. Note that there may be cases where, if the number of the element is clear and if it is not desired to distinguish the number of the element, the subscript is omitted. Also, there may be cases where, if the number of times repeated calculation is performed is clear and if it is not desired to distinguish the number of times repeated calculation is performed, the superscript is omitted.

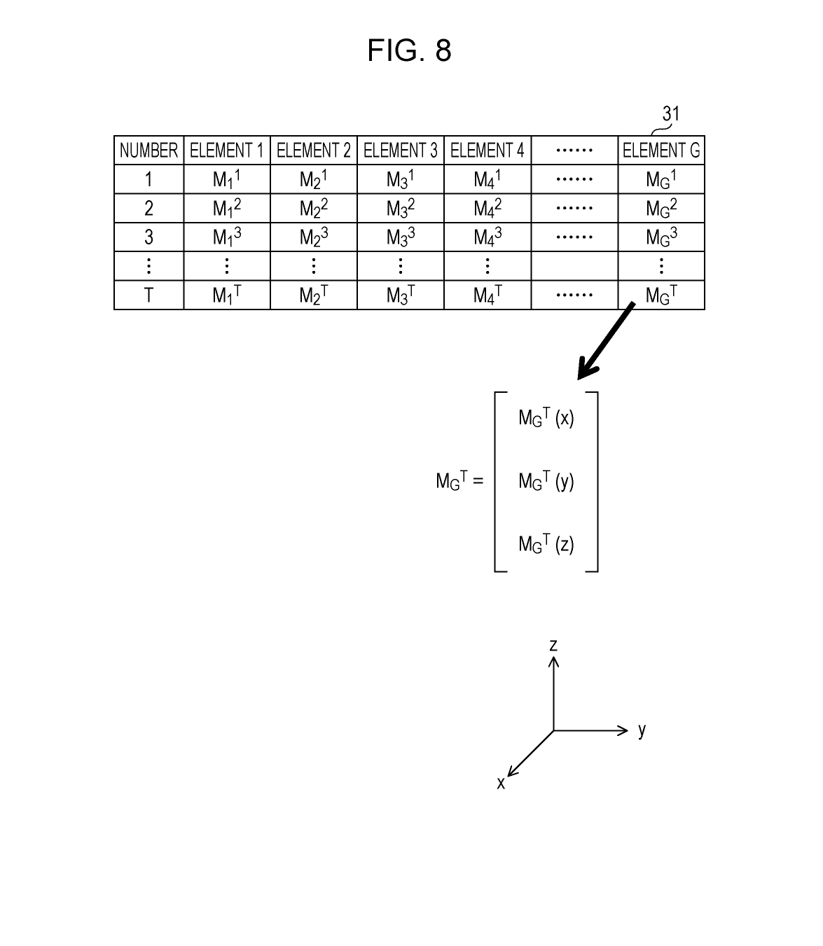

FIG. 8 is a table illustrating the layout of a record of a magnetization vector DB 31. The magnetization vector DB 31 is a DB that associates the number of times repeated calculation is performed and the magnetization vector M with each other. The magnetization vector DB 31 includes a number filed and fields with serial numbers, that is, an element 1 field to an element G field. In FIG. 8, G denotes the total number of the Gaussian numerical integration points 54 included in an analysis target. The magnetization vector DB 31 includes a single record for each repeated calculation.

In the number field, the number of times repeated calculation is performed is recorded. In the fields from the element 1 field to the element G field, each of the elements of the magnetization vector M associated with the Gaussian numerical integration point 54 of each number in the x, y, and z directions is recorded.

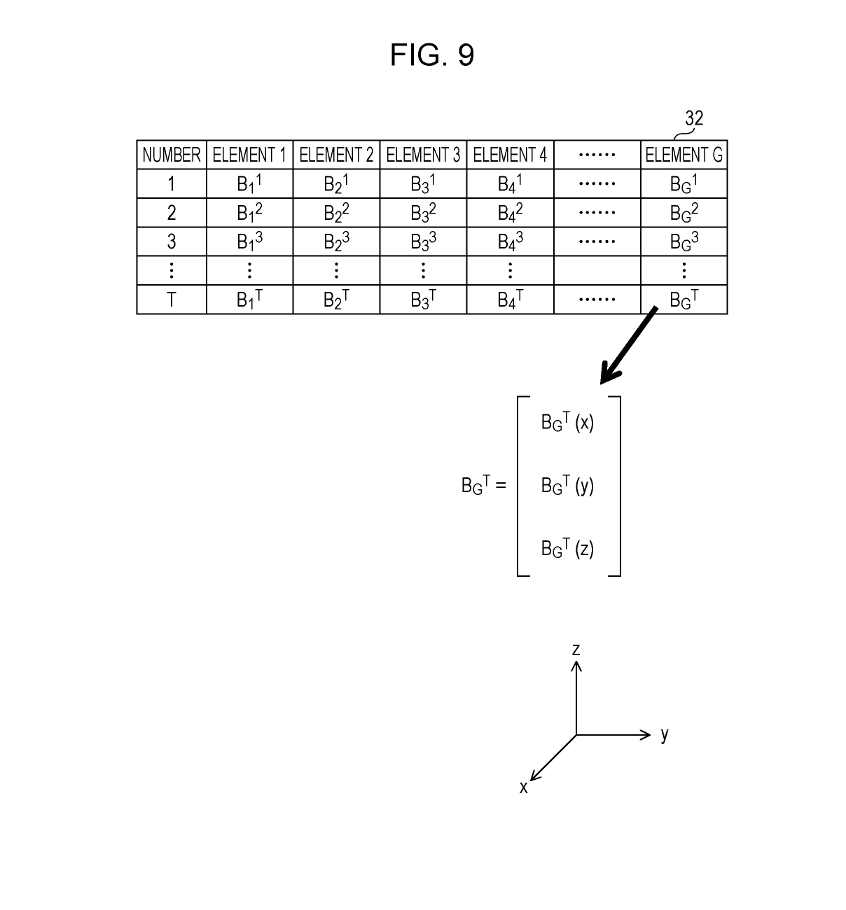

FIG. 9 is a table illustrating the layout of a record of a magnetic flux density vector DB 32. The magnetic flux density vector DB 32 is a DB that associates the number of times repeated calculation is performed and the magnetic flux density vector B with each other. The magnetic flux density vector DB 32 includes a number field and fields with serial numbers, that is, an element field 1 to an element G field. The magnetic flux density vector DB 32 includes a single record for each repeated calculation.

In the number field, the number of times repeated calculation is performed is recorded. In the fields from the element 1 field to the element G field, each of the elements of the magnetic flux density vector B associated with the Gaussian numerical integration point 54 of each number in the x, y, and z directions is recorded.

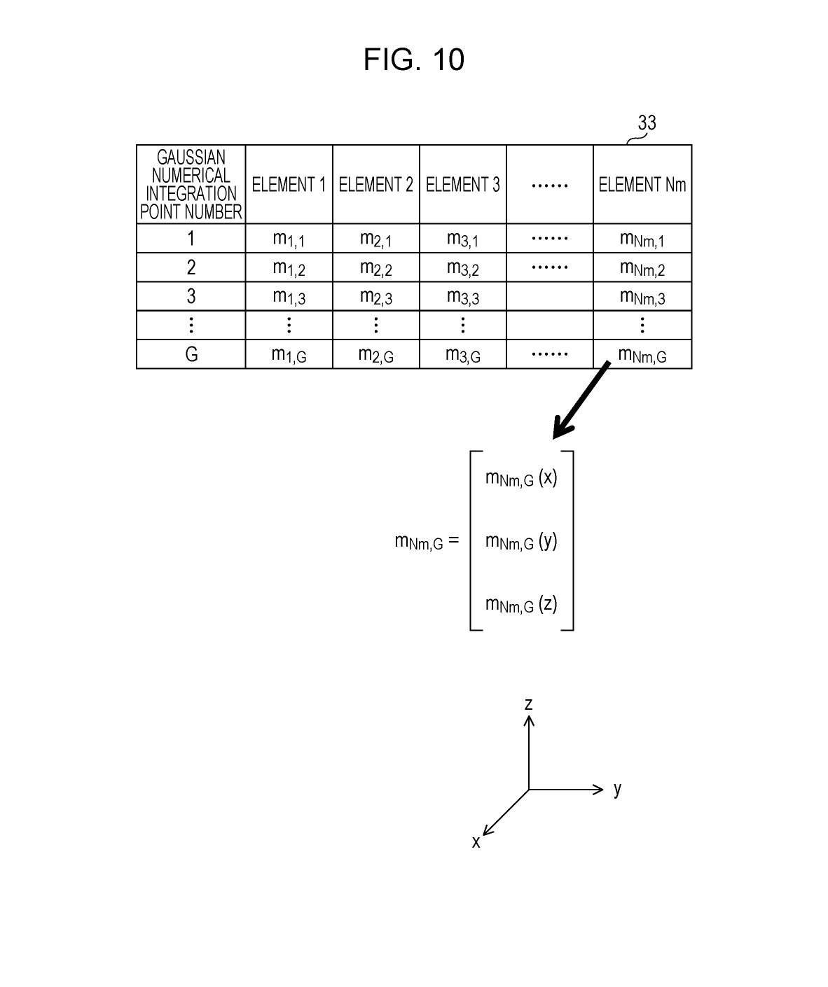

FIG. 10 is a table illustrating the layout of a record of a microscopic magnetization vector DB 33. The microscopic magnetization vector DB 33 is a DB that associates the number of an element and a microscopic magnetization vector m61 with each other. The microscopic magnetization vector DB 33 includes a Gaussian numerical integration point field and fields with serial numbers, that is, an element 1 field to an element Nm field. In FIG. 10, Nm denotes the number of the elements 58 in the divided element 56 including the Gaussian numerical integration point 54 with a number recorded in the Gaussian numerical integration point field. The microscopic magnetization vector DB 33 includes a single record for each single Gaussian numerical integration point 54. Note that, if there are divided elements 56 having different shapes in a mixed manner, the number of element fields may differ depending on the record.

In the Gaussian numerical integration point field, the number of each Gaussian numerical integration point 54 is recorded. In the fields from the element 1 field to the element Nm field, each of the elements of the microscopic magnetization vectors m61 associated with elements in the divided element 56 including the Gaussian numerical integration point 54 of each number recorded in the Gaussian numerical integration point field in the x, y, and z directions is recorded. Note that, when the number of the microscopic magnetization vector m61 is displayed, the number given to the corresponding element 58 and the number of the Gaussian numerical integration point 54 associated with the divided element 56 are displayed as a subscript, the numbers being separated by a comma. For example, a microscopic magnetization vector m_{Nm, G}ⁿ61 denotes the microscopic magnetization vector m61 associated with the Nmth element 58 in the divided element 56 including the Gth Gaussian numerical integration point 54 in the initial state of the nth repeated calculation. Each time repeated calculation is performed, the microscopic magnetization vector DB 33 is rewritten to the latest value.

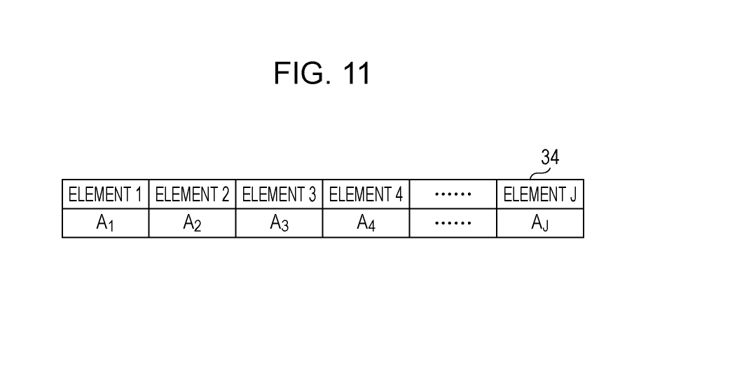

FIG. 11 is a table illustrating the layout of a record of a vector potential DB 34. The vector potential DB 34 is a DB that associates the number of each of the edge elements 51 and the corresponding vector potential A with each other. The vector potential DB 34 includes fields with serial numbers, that is, an element 1 field to an element J field. In FIG. 11, J denotes the total number of the edge elements 51 included in an analysis target. The vector potential DB 34 includes a single record. Note that each vector potential A is a vector quantity having an associated x, y, and z component.

In the fields from the element 1 field to the element J field, the vector potential A associated with the edge element 51 of each number is recorded. Each time iterative calculation is performed, the vector potential DB 34 is updated with a newly calculated value of the vector potential A.

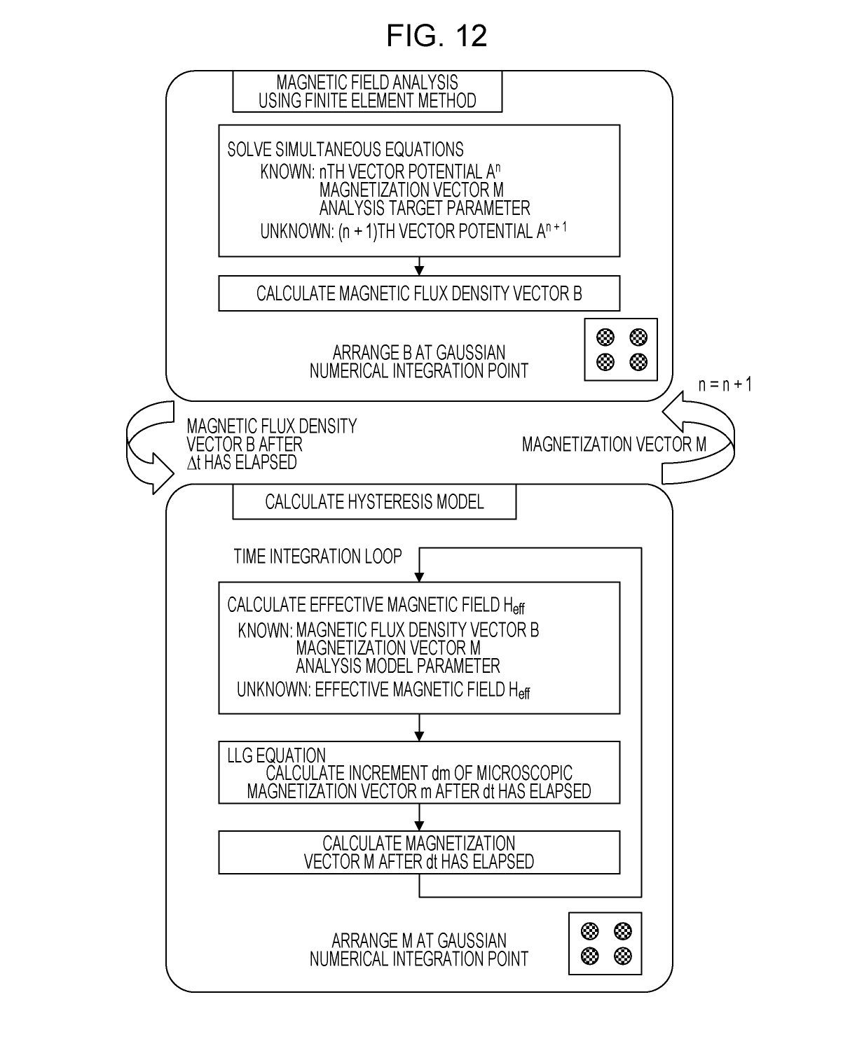

FIG. 12 is a chart illustrating an outline of a simulation method. In this embodiment, magnetic field analysis using a finite element method and hysteresis model calculation are alternately executed. The output of magnetic field analysis using a finite element method is the magnetic flux density vector B associated with each Gaussian numerical integration point 54. The output of hysteresis model calculation is the magnetization vector M associated with each Gaussian numerical integration point 54.

An outline of magnetic field analysis using a finite element method will be described. The CPU 12 solves J simultaneous equations of Expression (1), by using the nth vector potential Aⁿ and the nth magnetization vector Mⁿ, which are knowns, and parameters, such as a magnetic permeability or the like, which indicate characteristics of an analysis target, and calculates the (n+1)th vector potential A_{J}ⁿ⁺¹, which is an unknown.

$${A}_{J}^{n + 1} = {[ {\sum }_{g = 1}^{G} ( \frac{{C}_{IJ , g}}{Δ t} + {d}_{IJ , g} ) ]}^{- 1} {\sum }_{g = 1}^{G} ( - \frac{{C}_{IJ , g}}{Δ t} {A}_{J}^{n} + {e}_{I , g} {J}_{0} + {f}_{I , g} + {M}_{g} ) \qquad ( 1 )$$

where;

J: the number of the edge elements 51,

A_{J}ⁿ: an initial value of the vector potential A associated with the Jth edge element 51 in nth iterative calculation of a finite element method,

G: the number of the Gaussian numerical integration points 54 in the analysis target,

Δt: a first time that indicates a time interval for the iterative calculation of the finite element method,

C_{IJ, g}: a value that corresponds to the gth Gaussian numerical integration point 54,

d_{IJ, g}: a value that corresponds to the gth Gaussian numerical integration point 54,

e_{I, g}: a value that corresponds to the gth Gaussian numerical integration point 54,

f_{I, g}: a value that corresponds to the gth Gaussian numerical integration point 54,

J₀: an exciting current that is caused to flow in the lead 43,

M_{g}: the magnetization vector M that corresponds to the gth Gaussian numerical integration point 54, and

C_{IJ, g}, d_{IJ, g}, e_{I, g}, and f_{I,g} are elements in an arrangement that has been generated by the mesh division tool and stored in the auxiliary storage device 14.

Note that the same symbol is used to indicate the same parameter in expressions described below. Therefore, the description of a symbol that has already been described will be omitted when the symbol appears subsequently.

The CPU 12 acquires the vector potential A_{J}ⁿ that was calculated in previous iterative calculation from the vector potential DB 34. Note that, no record is recorded in the vector potential DB 34 by first iterative calculation, all of elements of the vector potential A_{J}ⁿ are set to a specific value, that is, for example, zero. The first time Δt is a time of about one nanosecond to one second, which is selected by a user in accordance with an analysis target and an object for which analysis is performed.

The CPU 12 records, in the vector potential DB 34, the vector potential A that was calculated in accordance with Expression (1).

The CPU 12 calculates the (n+1)th magnetic flux density vector B_{g}ⁿ⁺¹ associated with the gth Gaussian numerical integration point 54 in accordance with Expression (2).

$${B}_{g}^{n + 1} = {\sum }_{i = 1}^{J} ∇ {N}_{i , g} \times {A}_{i , g}^{n + 1} \qquad ( 2 )$$

### Where;

B_{g}ⁿ: the (n+1)th magnetic flux vector B associated with the gth Gaussian numerical integration point 54,

N_{i, g} an interpolation function set for the ith edge element 51 associated with the cell element 52 including the gth Gaussian numerical integration point 54, and

A_{i, g}ⁿ⁺¹: an initial value of the vector potential A associated with the ith edge element 51 that surrounds the cell element 52 including the gth Gaussian numerical integration point 54 in the (n+1)th iterative calculation of the finite element method.

An interpolation function N is a function that is used to indicate a physical quantity at an arbitrary point on an edge element 51. The interpolation function N is a function that has been used in analysis using a finite element method, and therefore, the description thereof will be omitted.

Thus, the CPU 12 completes single iterative calculation of the magnetic field analysis using the finite element method. The CPU 12 records the magnetic flux density vector B that has been calculated in accordance with Expression (2) in the magnetic flux density vector DB 32. Thereafter, the CPU 12 performs processing of hysteresis model calculation, an outline of which will be described below.

The CPU 12 calculates the (n+1)th effective magnetic field H_{eff, g}ⁿ⁺¹ associated with the gth Gaussian numerical integration point 54 in accordance with Expression (3).

$${H}_{eff , g}^{n + 1} = {H}_{ani , g} + \frac{{B}_{g}^{n + 1}}{{μ}_{0}} + \frac{( {M}_{g} )}{{μ}_{0}} + {H}_{external , g} \qquad ( 3 )$$

### Where;

H_{eff, g}ⁿ: the nth effective magnetic field associated with the gth Gaussian numerical integration point 54,

H_{ani, g}: a magneto-crystalline anisotropy magnetic field vector associated with the gth Gaussian numerical integration point 54,

μ₀: a vacuum magnetic permeability,

<M_{g}>: the magnetization vector M associated with the cell element 52 that includes the gth Gaussian numerical integration point 54, and

H_{external, g}: an external magnetic field vector associated with the gth Gaussian numerical integration point 54.

In performing modeling of an analysis target, the magneto-crystalline anisotropy magnetic field vector H_{ani, g} and the external magnetic field vector H_{external, g} are set, based on the physical property value of the analysis target and initial conditions for the analysis target, and are stored in the auxiliary storage device 14. The vacuum magnetic permeability μ₀ is a physical constant, and is stored in the auxiliary storage device 14.

The CPU 12 may generate a DB in which the effective magnetic field H_{eff, g}ⁿ⁺¹ that has been calculated in accordance with Expression (3) is recorded and store the DB in the auxiliary storage device 14.

The CPU 12 performs numerical integration of the LLG equation indicated in Expression (4), and calculates a microscopic magnetization vector m_{i, g}61 after a second time dt has elapsed. The microscopic magnetization vector m_{i, g}61 denotes the microscopic magnetization vector m61 associated with the ith element in the divided element 56 including the gth Gaussian numerical integration point 54.

$$\frac{d {m}_{i , g}}{d t} = - γ {m}_{i , g} \times {H}_{eff , g}^{n + 1} - γ α {m}_{i , g} \times {m}_{i , g} \times {H}_{eff , g}^{n + 1} \qquad ( 4 )$$

### Where;

m_{i, g} the ith microscopic magnetization vector m61 associated with the ith element 58 in the divided element 56 that includes the gth Gaussian numerical integration point 54,

dt: the second time that indicates a time interval of the iterative calculation of the LLG equation,

γ: a gyro magnetic constant, and

α: a damping constant.

The CPU 12 updates information recorded in the microscopic magnetization vector DB 33 with the microscopic magnetization vector m61 that has been calculated in accordance with Expression (4).

The gyro magnetic constant γ is a physical constant, and is stored in the auxiliary storage device 14. The damping constant α is a constant that is used in the LLG equation, and is stored in the auxiliary storage device 14. It is preferable to use, as the second time dt, a time of about one picosecond to several picoseconds.

The CPU 12 calculates the magnetization vector M_{g} that is an average of the microscopic magnetization vectors m61 in each divided element 56 in accordance with Expression (5).

$${M}_{g} = \frac{1}{Nm} {\sum }_{i = 1}^{Nm} {m}_{i , g} \qquad ( 5 )$$

where Nm denotes the number of elements 58 in the divided element 56 that includes the gth Gaussian numerical integration point 54.

The CPU 12 calculates the effective magnetic field H_{eff, g}ⁿ⁺¹ in accordance with Expression (3) again by using the magnetization vector M_{g} that has been calculated in accordance with Expression (5) and performs iterative calculation to calculate a next magnetization vector M_{g} using Expression (4) and Expression (5) in order.

If it is determined, based on a predetermined condition, that the magnetization vector M_{g} has converged, the CPU 12 terminates iterative processing of hysteresis model calculation. The CPU 12 records the magnetization vector M that has been calculated in accordance with Expression (5) in the magnetization vector DB 31. Thereafter, the CPU 12 causes the process to return to the magnetic field analysis using the finite element method, and calculates a new vector potential A_{J}, based on the simultaneous equations of Expression (1), using the magnetization vector M_{g} that has been obtained by the hysteresis model calculation.

By performing the above-described iterative calculation in which magnetic field analysis using a finite element method and hysteresis model calculation are alternately performed, the CPU 12 calculates the magnetization vector M and the magnetic flux density vector B for every first time Δt, and records a result of the calculation. If a predetermined condition is satisfied, the CPU 12 terminates the processing.

By visualizing the magnetization vector M recorded in the magnetization vector DB 31 or the magnetic flux density vector B recorded in the magnetic flux density vector DB 32, the user may know a distribution state of magnetism that is generated by the inductor 41, which is an analysis target, the intensity of the magnetism, or the like. Also, by calculating all of magnetic fluxes passing through the inductor 41 from the magnetic flux density vector B and dividing a result of the calculation by the exciting current J₀ that is caused to flow through the lead 43, the inductance of the inductor 41 may be calculated.

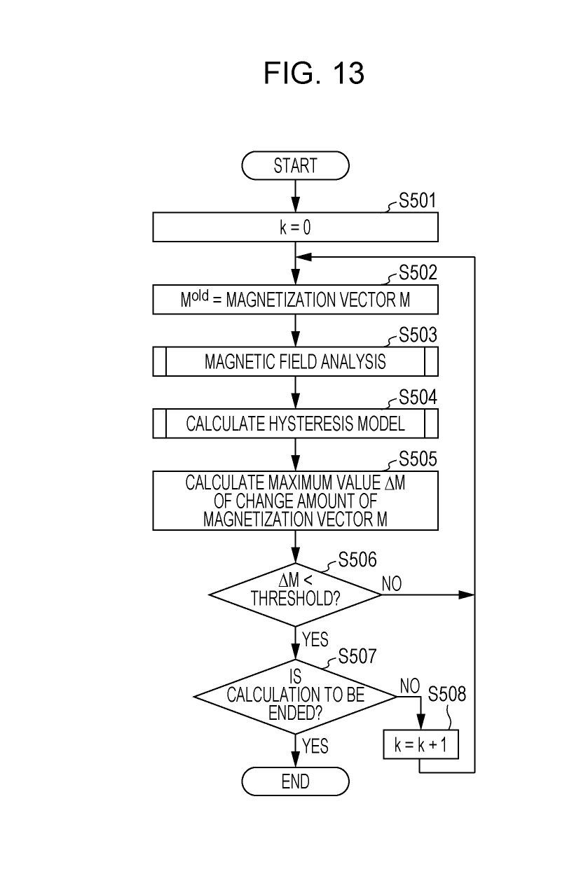

FIG. 13 is a flow chart illustrating a flow of processing of a program. A flow of processing of a program will be described with reference to FIG. 13.

The CPU 12 sets a counter k to an initial value 0 (Step S501). The CPU 12 acquires a record that was recorded last from the magnetization vector DB 31, and records the acquired record in a variable vector M^{old} (Step S502). Note that, if there is not any record that was recorded in the magnetization vector DB 31 by first iterative calculation, all of elements of the variable vector M^{old} are set to, for example, zero.

The CPU 12 starts a subroutine of magnetic field analysis (Step S503). The subroutine of magnetic field analysis is a subroutine in which the magnetic field analysis using the finite element method, which has been described with reference to FIG. 12, is performed. A flow of processing of the subroutine of the magnetic field analysis will be described later. The CPU 12 starts a subroutine of hysteresis model calculation (Step S504). The subroutine of the hysteresis model calculation is a subroutine in which the hysteresis model calculation, which has been described with reference FIG. 12, is performed. A flow of processing of the subroutine of the hysteresis model calculation will be described later.

The CPU 12 calculates a maximum value ΔM of a change amount of the magnetization vector M in accordance with Expression (6) (Step S505). Specifically, a difference vector between the magnetization vector M^{k} that was calculated in the subroutine of the hysteresis model calculation of Step S504 and the variable vector M^{old} that was recorded in Step S502 is calculated for each Gaussian numerical integration point 54. The absolute value of each difference vector is calculated, and the maximum value ΔM thereof is extracted.

ΔM=max(|M_{g}^{k}−M_{g}^{old}|) (6)

The CPU 12 determines whether or not ΔM that was calculated in Step S505 is less than a predetermined threshold (Step S506). If ΔM is not less than the predetermined threshold (NO in Step S506), the CPU 12 causes the process to return Step S502.

If ΔM is less than the predetermined threshold (YES in Step S506), the CPU 12 determines whether or not the calculation is to be terminated (Step S507). Whether or not the calculation is to be terminated is determined, for example, depending on whether or not the counter k exceeds a predetermined value. Also, whether or not the calculation is to be terminated may be determined depending on whether or not each of the change amounts of the magnetization vector M and the magnetic flux density vector B has converged to a predetermined value or less, as compared to Step S507, which has been previously performed.

If it is determined that the calculation is not to be terminated (NO in Step S507), the CPU 12 adds 1 to the counter k (Step S508). The CPU 12 causes the process to return to Step S502. If it is determined that the calculation is to be terminated (YES in Step S507), the CPU 12 terminates the processing.

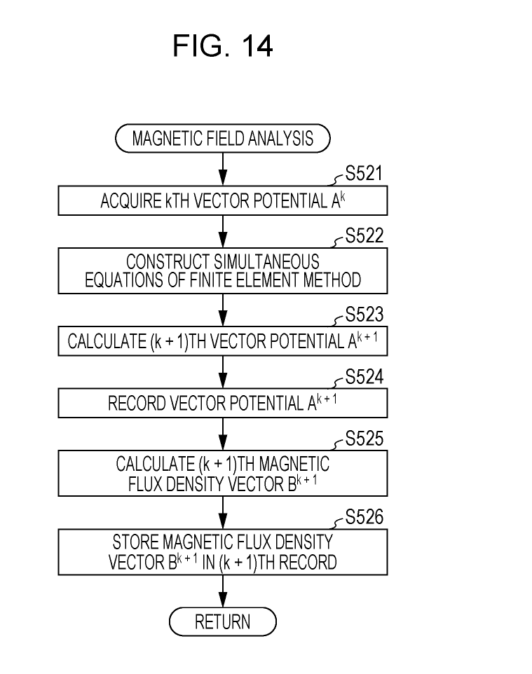

FIG. 14 is a flow chart illustrating a flow of processing of a subroutine of magnetic field analysis. The subroutine of the magnetic field analysis is a subroutine in which the magnetic field analysis using the finite element method, which has been described with reference to FIG. 12. A flow of processing of the subroutine of the magnetic field analysis will be described with reference to FIG. 14.

The CPU 12 acquires the vector potential A that has been recorded from the vector potential DB 34 (Step S521). The vector potential that was acquired in Step S521 is an initial value of the vector potential A of iterative calculation that corresponds to the counter k, and therefore, will be referred to as a vector potential A^{k} in the following description.

The CPU 12 constructs simultaneous equations of a finite element method (Step S522). Specifically, the CPU 12 calculates a coefficient of each term of Expression (1), which has been described above, using an arrangement that was output by the mesh arrangement tool. The CPU 12 calculates a (k+1)th vector potential A^{k+1} in accordance with Expression (1) (Step S523). The CPU 12 records the vector potential A^{k+1}, which was calculated in Step S523, in the vector potential DB 34 (Step S524).

The CPU 12 calculates a (k+1)th magnetic flux density vector B^{k+1} in accordance with Expression (2), which has been described above (Step S525). The CPU 12 records the magnetic flux density vector B^{k+1}, which was calculated in Step S525, in the magnetic flux density vector DB 32 (Step S526). Thus, the CPU 12 terminates the processing.

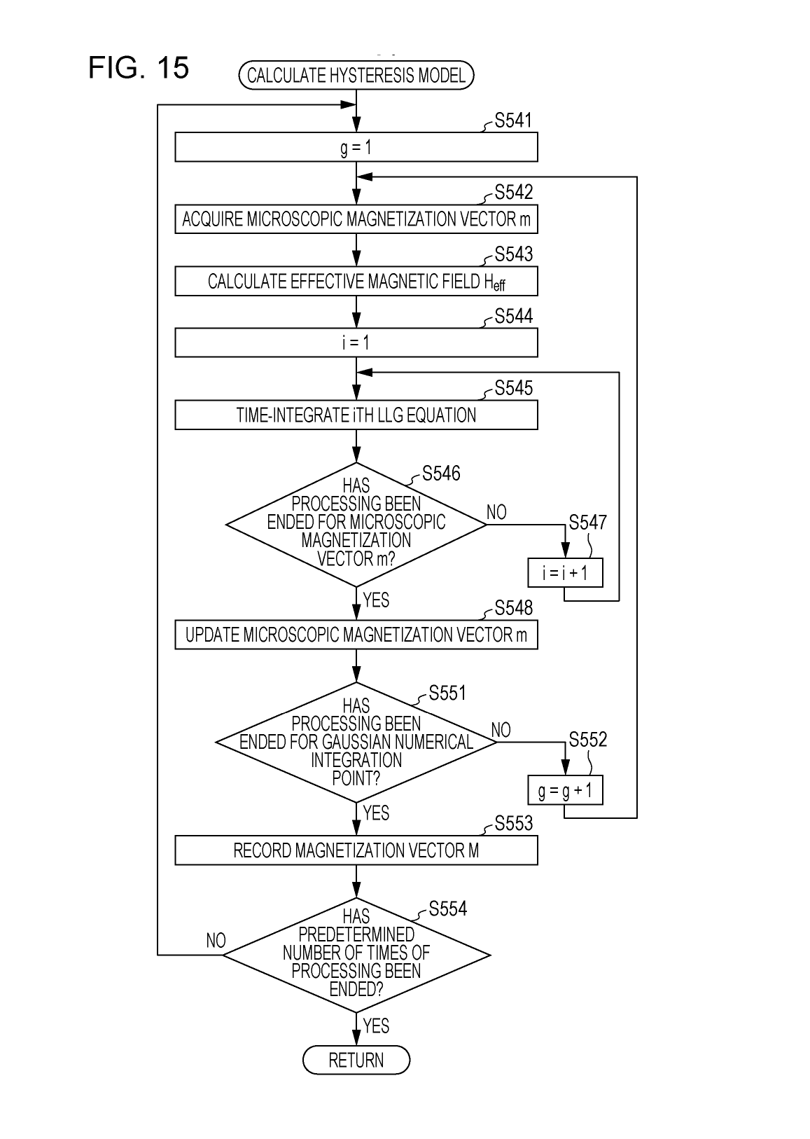

FIG. 15 is a flow chart illustrating a flow of processing of a subroutine of hysteresis model calculation. The subroutine of the hysteresis model calculation is a subroutine in which the hysteresis model calculation, which has been described with reference to FIG. 12, is preformed. A flow of processing of the hysteresis model calculation will be described with reference to FIG. 15.

The CPU 12 sets a counter g to an initial value 1 (Step S541). The CPU 12 acquires the microscopic magnetization vector m61 associated with the gth Gaussian numerical integration point 54 from the microscopic magnetization vector DB 33 (Step S542). Specifically, the CPU 12 acquires a gth record from the microscopic magnetization vector DB 33. The CPU 12 calculates the gth effective magnetic field H_{eff} in accordance with Expression (3) (Step S543). In this case, for B_{g}ⁿ⁺¹ in Expression (3), a record that was recorded last in the magnetic flux density vector DB 32 is acquired and thus is used. For <M_{g}> in Expression (3), a vector obtained by averaging the microscopic magnetization vectors m61 acquired in Step S541 for each cell element 52 is used.

The CPU 12 sets a counter i to an initial value 1 (Step S544). The CPU 12 performs time integration of the ith LLG equation (Step S545). Specifically, the CPU 12 calculates dm_{i, g}, which is an increment of the microscopic magnetization vector m61 during the second time dt, in accordance with Expression (4), and adds a result of the calculation to the microscopic magnetization vector m_{i, g}61, which was acquired in Step S542.

The CPU 12 determines whether or not processing of the microscopic magnetization vector m61 associated with the gth Gaussian numerical integration point 54 has been terminated (Step S546). Specifically, the CPU 12 determines whether or not time integration for all of the microscopic magnetization vectors m61 associated with the elements 58 in the divided element 56 that includes the gth Gaussian numerical integration point 54, based on Expression (4), has been terminated.

If it is determined that the processing has not been terminated (NO in Step S546), the CPU 12 adds 1 to the counter i (Step S547). Thereafter, the CPU 12 causes the process to return to Step S545. If it is determined that the processing has been terminated (YES in Step S546), the CPU 12 updates the microscopic magnetization vector m61 that was recorded in the gth record of the microscopic magnetization vector DB 33 to a value calculated in Step S545 (Step S548).

The CPU 12 determines whether or not processing has been terminated for all of the Gaussian numerical integration points 54 (Step S551). If it is determined that the processing has not been terminated (NO in Step S551), the CPU 12 adds 1 to the counter g (Step S552). Thereafter, the CPU 12 causes the process to return to Step S542.

If it is determined that the processing has been terminated (YES in Step S551), the CPU 12 records the magnetization vector M in the magnetization vector DB 31 (Step S553). Specifically, the CPU 12 averages the microscopic magnetization vectors m61 for each the divided element 56 to calculate the magnetization vector M. The CPU 12 generates a new record in the magnetization vector DB 31, and records the magnetization vector M.

The CPU 12 determines whether or not iterative calculation has been terminated a predetermined number of times (Step S554). The predetermined number of times is, for example, about 300 to 400. If it is determined that the processing has not been terminated (NO in Step S554), the CPU 12 causes the process to return to Step S541. If it is determined that the processing has been terminated (YES in Step S554), the CPU 12 terminates the processing.

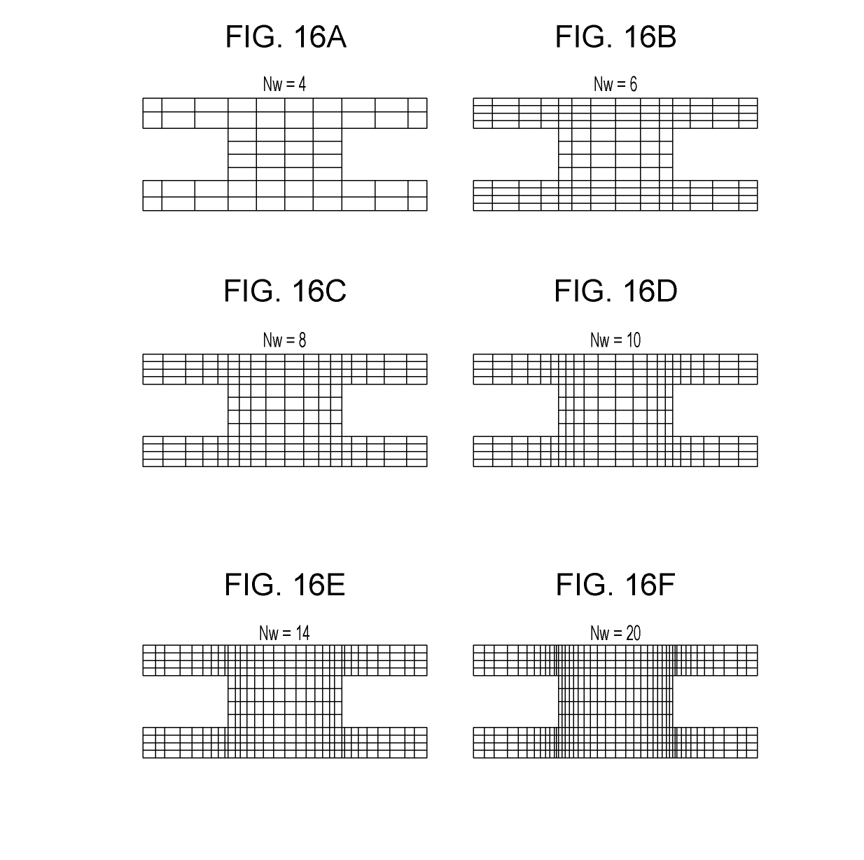

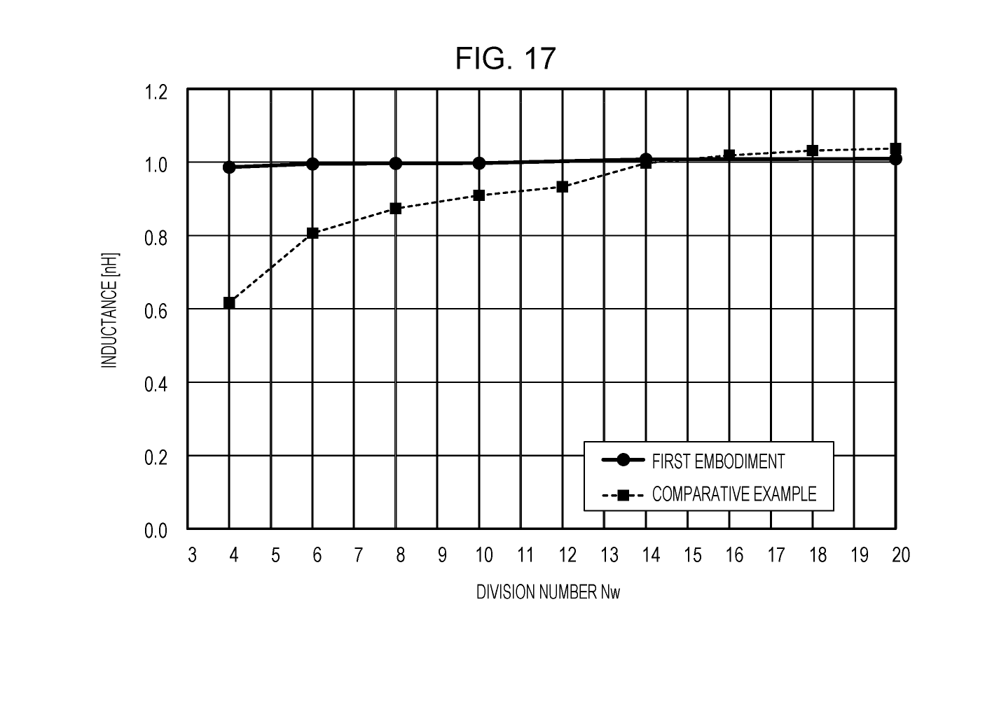

FIG. 16A to FIG. 16F are views each illustrating an example in which the number of divisions of an analysis target is changed. FIG. 17 is a graph illustrating a convergent state of an analysis result. Characteristics of the program according to this embodiment will be described with reference to FIG. 16A, FIG. 16B, and FIG. 17.

In general, in analysis that is performed using a finite element method, as the number of divisions of an analysis target increases, calculation accuracy increases and, when the number of divisions is a certain number or more, a calculation result converges. On the other hand, as the number of divisions of an analysis target increases, a calculation amount increases. Therefore, in performing analysis using a finite element method, preliminary analysis is performed in advance to determine the number of divisions, which is to be used.

FIG. 16A to FIG. 16F are views illustrating example models that were used in a preliminary examination. FIG. 16A to FIG. 16F are front views of an analysis target according to this embodiment, illustrating only the core 42 of the analysis target. The number of divisions is denoted by a division number Nw that indicates the number of divided parts into which a narrow part of the core 42 is divided in a lateral direction of each of FIG. 16A to FIG. 16F. FIG. 16A illustrates a case of the division number Nw=4, FIG. 16B illustrates a case of the division number Nw=6, FIG. 16C illustrates a case of the division number Nw=8, FIG. 16D illustrates a case of the division number Nw=10, FIG. 16E illustrates a case of the division number Nw=14, and FIG. 16F illustrates a case of the division number Nw=20. Note that, when viewed from a direction other than the front, the core 42 is divided in a similar manner to that in FIG. 16A to FIG. 16F. Also, the lead 43 and circumambient air are divided in a similar manner to that in which the core 42 is divided.

FIG. 17 is a graph illustrating an analysis result obtained by inputting each of the models illustrated in FIG. 16A to FIG. 16F to the program according to this embodiment to calculate the inductance of the inductor 41 of an analysis target. In FIG. 17, the abscissa axis indicates the division number Nw. The ordinate axis indicates the inductance. The unit for the ordinate axis is nano-Henry. Each black circle indicates a result of calculation performed using the program according to this embodiment. Each black square indicates a result in a comparative example, which was obtained by analyzing the corresponding one of the same models using the known method described in Japanese Laid-open Patent Publication No. 2013-131072.

In this embodiment, the inductance is substantially the same in analysis results for the cases in which the division number is 4 to 20. Therefore, the division number Nw is preferably 4. On the other hand, in the comparative example, the inductance largely varies in analysis results for the cases in which the division number Nw is 4 to 14. Therefore, it is preferable to use 16 as the division number Nw.

Thus, in the program according to this embodiment, there are less fluctuations in analysis results in terms of the value of the division number Nw, as compared to the comparative example. Therefore, a preliminary examination in which the number of divisions is determined may be terminated in a short time, and a proper number of divisions may be set.

Next, an rough estimate of a difference in calculation amount between the program according to this embodiment and the comparative example will be described. As described above, the following description will be given using, as an example, a case where, when the program according to this embodiment is used, the division number Nw is 4 and, in the comparative example, the division number Nw is 16. The division number Nw according to this embodiment is ¼ of that of the comparative example. Each of the numbers of the edge elements 51 and the cell elements 52 is proportional to the cube of the number of divisions. Therefore, each of the numbers of the edge elements 51 and the cell elements 52 according to this embodiment is 1/64 of the corresponding one of the numbers of the edge elements 51 and the cell elements 52 in the comparative example. A calculation amount of a finite element method is proportional to the number of elements. Therefore, the calculation amount of the finite element method according to this embodiment is 1/64 times of that of the comparative example due to the difference in the division number Nw.

In this embodiment, the magnetization vector M and the magnetic flux density vector B are calculated for each Gaussian numerical integration point 54. As described above, a single one of the cell elements 52 includes eight Gaussian numerical integration points 54. On the other hand, in the comparative example, the magnetization vector M and the magnetic flux density vector B are calculated for each cell element 52. The amount of hysteresis model calculation is proportional to the number of points at which the magnetization vector M and the magnetic flux density vector B are calculated. Therefore, the amount of hysteresis model calculation according to this embodiment is eight times of that of the comparative example due to performing calculation for each Gaussian numerical integration point 54.

When 1/64 times, which is the ratio of the calculation amount of the finite element method, and eight times, which is the ratio of the amount of hysteresis model calculation, are multiplied together, and the calculation amount according to this embodiment is ⅛ of that of the comparative example.

Thus, using the program according to this embodiment, a proper number of divisions may be determined using a smaller preliminary examination amount than that of the comparative example, and furthermore, the calculation amount when analysis is performed with the proper number of divisions is reduced to ⅛ of that of the comparative example. That is, highly accurate simulation may be performed with a small calculation amount.

A rough estimate of the calculation amount when two-dimensional analysis is performed on a similar calculation target using quadrangular elements will be described using, as an example, a case where the proper division number Nw is ¼. Each of the numbers of the edge elements 51 and the cell elements 52 in the two-dimensional analysis is proportional to the square of the number of divisions. Therefore, the calculation amount of the finite element method is 1/16. Also, as described above, a single quadrangular element includes four Gaussian numerical integration points 54, and therefore, the amount of hysteresis model calculation is four times larger. Accordingly, when quadrangular elements are used, the calculation amount is reduced to ¼ of that of the comparative example.

### Second Embodiment

This embodiment is related to a program used for determining, based on whether or not the magnetization vector M has converged, whether or not iterative processing of hysteresis model calculation is terminated, or the like. Note that the description of each part in common with the first embodiment will be omitted.

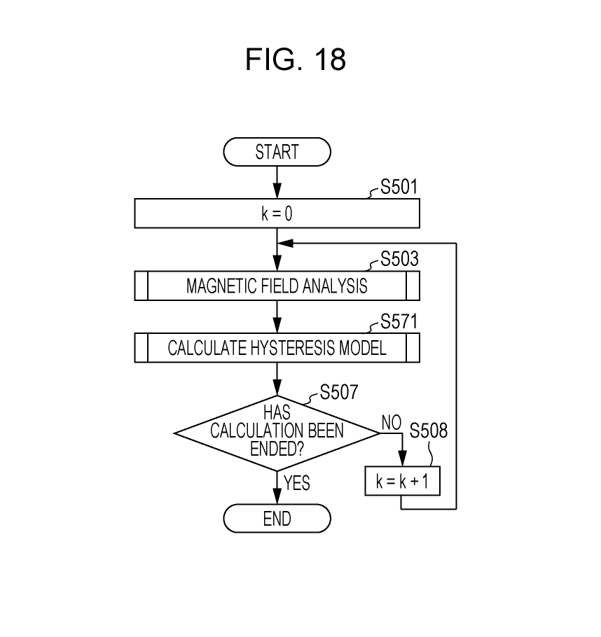

FIG. 18 is a flow chart illustrating a flow of processing of a program according to a second embodiment. A flow of processing according to this embodiment will be described with reference to FIG. 18.

The CPU 12 sets the counter k to an initial value 0 (Step S501). The CPU 12 starts a subroutine of magnetic field analysis (Step S503). As the subroutine of the magnetic field analysis, the same subroutine as the subroutine that has been described with reference to FIG. 14 is used.

The CPU 12 starts a subroutine of hysteresis model calculation (Step S571). The subroutine of the hysteresis model calculation is a subroutine in which the hysteresis model calculation, which has been described with reference to FIG. 12, is performed. A flow of processing of the subroutine of the hysteresis model calculation according to this embodiment will be described later.

The CPU 12 determines whether or not calculation is to be terminated (Step S507). Whether or not the calculation is to be terminated is determined, for example, depending on whether or not the counter k exceeds a predetermined value.

If it is determined that the calculation is not to be terminated (NO in Step S507), the CPU 12 adds 1 to the counter k (Step S508). The CPU 12 causes the process to return to Step S503. If it is determined that the calculation is to be terminated (YES in Step S507), the CPU 12 terminates the processing.

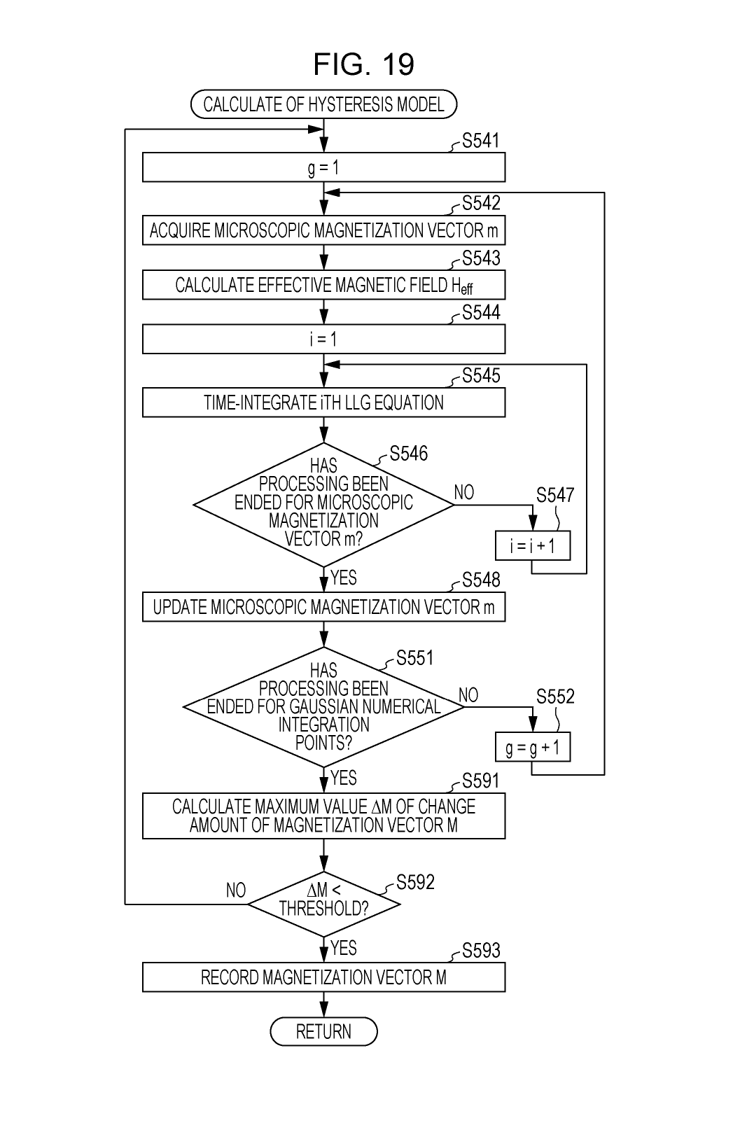

FIG. 19 is a flow chart illustrating a flow of processing of a subroutine of hysteresis model calculation according to the second embodiment. The subroutine of the hysteresis model calculation is a subroutine in which the hysteresis model calculation, which has been described with reference to FIG. 12, is performed. A flow of processing of the hysteresis model calculation according to this embodiment will be described with reference to FIG. 19.

Up to Step S552, the same processing as that of the subroutine of the hysteresis model calculation according to the first embodiment, which has been described with reference to FIG. 15, is performed, and therefore, the description thereof will be omitted.

If it is determined that processing has been terminated for all of the Gaussian numerical integration points 54 (YES in Step S551), the CPU 12 calculates a maximum value ΔM of the change amount of the magnetization vector M in accordance with Expression (7) (Step S591). Specifically, first, the magnetization vector M^{k} is calculated, based on the microscopic magnetization vector DB 33 that was updated in Step S548. The magnetization vector M^{k-1} that was recorded last is acquired from the magnetization vector DB 31. A difference vector between M^{k} and M^{k-1} is calculated for each Gaussian numerical integration point 54. The absolute value of each difference vector is calculated, and the maximum value ΔM thereof is extracted.

ΔM=max(|M_{g}^{k}−M_{g}^{k-1}|) (7)

The CPU 12 determines whether or not ΔM, which was calculated in Step S505, is less than a predetermined threshold (Step S592). If ΔM is not less than the predetermined threshold (NO in Step S592), the CPU 12 causes the process to return to Step S541. If ΔM is less than the predetermined threshold (YES in Step S592), the CPU 12 records the magnetization vector M in the magnetization vector DB 31 (Step S593). Thereafter, the CPU 12 terminates processing.

According to this embodiment, the number of times hysteresis model calculation is repeated may be set to a minimum number.

Note that, in Step S592, based on whether or not ΔM is less than the threshold and the number of times a loop from the Step S541 to Step S592 is iterated in combination, whether or not the loop may be terminated may be determined. For example, if ΔM is less than the threshold and the number of times the loop is iterated exceeds a predetermined number of times, YES may be given in Step S592. Also, if ΔM is less than the threshold or if the number of times the loop is iterated exceeds a predetermined number of times, YES may be given in Step S592.

### Third Embodiment

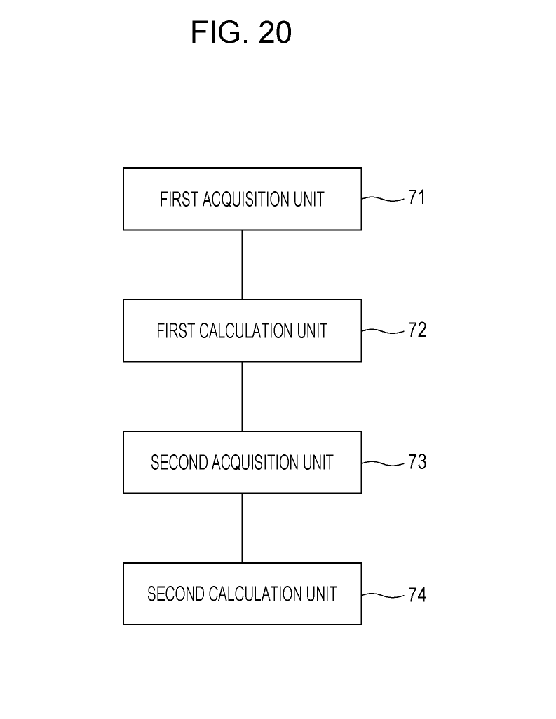

FIG. 20 is a functional block diagram illustrating an operation of a simulation device 10 according to a third embodiment. The simulation device 10 operates in a manner described below, based on control performed by the CPU 12.

A first acquisition unit 71 acquires information associated with an edge element 51 with which a calculation target is modeled and information of Gaussian numerical integration points 54 in a cell element 52 surrounded by a plurality of edge elements 51. A first calculation unit 72 calculates a magnetic flux density vector B for each Gaussian numerical integration point 54 after a predetermined first time Δt has elapsed, based on the information associated with the edge elements 51, using a finite element method. A second acquisition unit 73 acquires microscopic magnetization vectors m61 of a plurality of elements 58 associated with the Gaussian numerical integration point 54. A second calculation unit 74 calculates a magnetization vector M for each Gaussian numerical integration point 54 after a second time dt, which is shorter than the first time Δt, has elapsed, based on the magnetic flux density vector B and the microscopic magnetization vectors m61.

### Fourth Embodiment

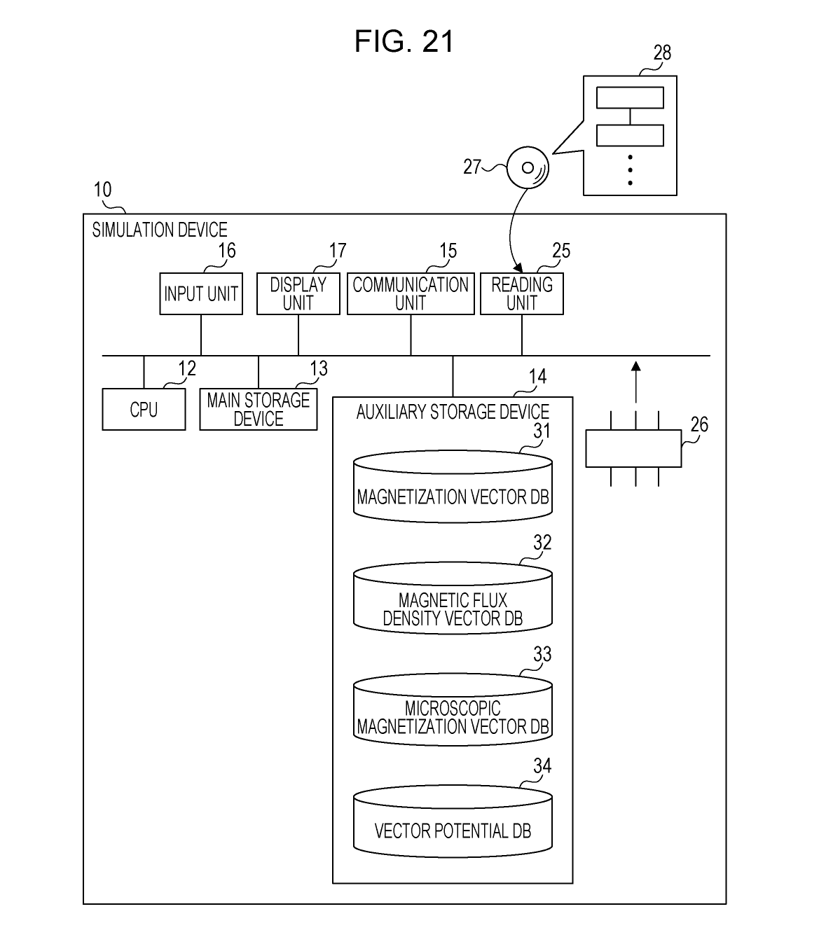

A fourth embodiment is an embodiment in which the simulation device 10 is realized by causing a general-purpose computer and a program 28 to operate in combination. FIG. 21 is a diagram illustrating a configuration of the simulation device 10 according to the fourth embodiment. The configuration of this embodiment will be described with reference to FIG. 21. Note that the description of a part in common with the first embodiment will be omitted.

The simulation device 10 according to this embodiment includes a CPU 12, memory, such as a main storage device 13, an auxiliary storage device 14, or the like, a communication unit 15, an input unit 16, a display unit 17, a reading unit 25, and a bus. The simulation device 10 may be an information processing device, such as a general-purpose personal computer or the like, and the CPU 12 may be a processor, such as a MPU or the like.

The program 28 is recorded in a portable recording medium 27. The CPU 12 reads the program 28 via the reading unit 25, and stores the program 28 in the auxiliary storage device 14. Also, the CPU 12 may reads the program 28 stored in semiconductor memory 26, such as flash memory or the like, which is mounted in the simulation device 10. Furthermore, the CPU 12 may download the program 28 from another server computer (not illustrated) which is coupled thereto via the communication unit 15 and a network (not illustrated), and store the program 28 in the auxiliary storage device 14.

The program 28 is installed as a control program of the simulation device 10, is loaded to the main storage device 13, and is executed. Thus, the information processing device functions as the above-described simulation device 10.

Technical features (components) described in each of the above-described embodiments may be combined with one another, and such combination makes it possible to form a new technical feature.

The embodiments disclosed herein are provided merely for illustrative purpose in every respect and are not intended to be limiting in any aspect. The scope of the present disclosure is defined by the scope of claims rather than the above-described description, and is intended to include any modifications within the scope and meaning equivalent to the terms of the claims.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A simulation device comprising:
a memory; and
a processor coupled to the memory and configured to execute a process including;
first acquisition processing of acquiring information associated with edge elements with which a calculation target is modeled and information of Gaussian numerical integration points in a cell element surrounded by the edge elements;
first calculation processing of calculating a magnetic flux density vector for each of the Gaussian numerical integration points, using a finite element method, based on the information associated with the edge elements;
second acquisition processing of acquiring a plurality of microscopic magnetization vectors associated with the Gaussian numerical integration points; and
second calculation processing of calculating a magnetization vector for each of the Gaussian numerical integration points, based on the magnetic flux density vector and the microscopic magnetization vectors.

2. The simulation device according to claim 1,
wherein, in the first calculation processing, the magnetic flux density vector after a predetermined first time has elapsed is calculated, and
in the second calculation processing, the magnetization vector after a second time which is shorter than the first time has elapsed is calculated.

3. The simulation device according to claim 1,
wherein the cell element is divided into divided elements each of which includes the single corresponding one of the Gaussian numerical integration points, and
each of the Gaussian numerical integration points is associated with the microscopic magnetization vector arranged in the corresponding one of the divided elements, which includes the Gaussian numerical integration point.

4. The simulation device according to claim 2,
wherein, in the second calculation processing, the magnetization vector is calculated by calculating, based on the magnetic flux vector that was calculated in the first calculation processing and the microscopic magnetization vector that was acquired in the second acquisition processing, a microscopic magnetization vector after the predetermined second time has elapsed and averaging the microscopic magnetization vector for each Gaussian numerical integration point associated with the microscopic magnetization vector.

5. The simulation device according to claim 1,
wherein, in the first acquisition processing, a vector potential associated with each of the edge elements and a magnetization vector associated with each of the Gaussian numerical integration points are acquired.

6. The simulation device according to claim 1,
wherein, in the first acquisition processing, the magnetization vector calculated in the second calculation processing is acquired.

7. The simulation device according to claim 1,
wherein, in the second calculation processing, the magnetization vector is calculated based on a magnetic body model that represents a magnetic hysteresis characteristic.

8. The simulation device according to claim 2,
wherein the second calculation processing includes
first iterative processing of iteratively calculating the magnetization vector after a third time which is shorter than the second time has elapsed a predetermined number of times, and
convergence determination processing of determining whether or not the magnetization vector has converged, and
if it is determined in the convergence determination processing that the magnetization vector has not converged, the first iterative processing is performed again.

9. The simulation device according to claim 2,
wherein the second calculation processing includes
third calculation processing of calculating a magnetization vector after a third time which is shorter than the second time has elapsed,
convergence determination processing of determining whether or not the magnetization vector has converged, and
second iterative processing of iterating, if it is determined in the convergence determination processing that the magnetization vector has not converged, the third calculation processing and the convergence determination processing.

10. The simulation device according to claim 1,
wherein the second acquisition processing includes
third acquisition processing of acquiring the number of the plurality of microscopic magnetization vectors associated with the Gaussian numerical integration points and a magnetization vector associated with the associated one of the Gaussian numerical integration points, and
allocation processing of allocating a component for each of the microscopic magnetization vectors, wherein an averaged microscopic magnetization vectors matches the magnetization vector.

11. The simulation device according to claim 1,
wherein the cell element is hexahedral in shape.

12. The simulation device according to claim 1,
wherein the cell element is tetrahedral in shape.

13. A simulation program for causing a computer to execute a process, which is stored in a non-transitory computer-readable medium, the process comprising:
calculating, based on information associated with edge elements with which an acquired calculation target is modeled and information of Gaussian numerical integration points in a cell element surrounded by the edge elements, using a finite element method, a magnetic flux density vector for each of the Gaussian numerical integration points, and
calculating a magnetization vector for each of the Gaussian numerical integration points, based on the magnetic flux density vector and a plurality of microscopic magnetization vectors associated with the Gaussian numerical integration points.

14. A simulation method for causing a computer to execute a process, the process comprising:
calculating, based on information associated with edge elements with which an acquired calculation target is modeled and information of Gaussian numerical integration points in a cell element surrounded by the plurality of edge elements, using a finite element method, a magnetic flux density vector for each of the Gaussian numerical integration points, and
calculating a magnetization vector for each of the Gaussian numerical integration points, based on the magnetic flux density vector and a plurality of microscopic magnetization vectors associated with the Gaussian numerical integration points.
